(19) United States
(12) Patent Application Publication
(10) Pub. No.: US 2026/0204905 A1
(43) Pub. Date: Jul. 16, 2026

(54) Spectral Correlation Function-based Detection and Classification Method for Grid Signal Distortions

(71) Applicant: UT-Battelle, LLC, Oak Ridge, TN (US)

(72) Inventors: Ozgur Alaca, Knoxville, TN (US); Ali Riza Ekti, Knoxville, TN (US); Aaron Wilson, Knoxville, TN (US); John Holliman, Oak Ridge, TN (US); Elizabeth Piersall, Knoxville, TN (US); Nils M. Stenvig, Maryville, TN (US)

(73) Assignee: UT-Battelle, LLC, Oak Ridge, TN (US)

(21) Appl. No.: 19/177,365

(22) Filed: Apr. 11, 2025

Related U.S. Application Data
(60) Provisional application No. 63/655,747, filed on Jun. 4, 2024.

(51) Int. Cl. H02J 3/0012; G01R 23/16; H02J 13/12; H02J 103/30

(52) U.S. Cl. CPC H02J 3/0012; G01R 23/16; H02J 13/12; H02J 2103/30

(57) ABSTRACT

Systems and methods for operating a power grid-based system. The methods comprising: determining, by the processor, a spectral correlation function for a power grid signal being monitored; applying, by the processor, a trained classification model to the spectral correlation function, the trained classification model comprising a machine learning model trained to classify power grid signals based on power grid signal distortions; assigning, by the processor, a power grid distortion classification to the power grid signal based on an output of the trained classification model; and controlling operation(s) of an electrical device of the power grid-based system based on the power grid distribution classification.

### CROSS-REFERENCE TO RELATED APPLICATION(S)

The present application claims priority to and the benefit of U.S. Provisional Patent Application Ser. No. 63/655,747 which was filed on Jun. 4, 2024. The content of this Provisional Patent Application is incorporated by reference in its entirety.

### STATEMENT REGARDING FEDERALLY SPONSORED RESEARCH AND DEVELOPMENT

The technologies described herein were developed with government support under Contract No. DE-AC05-00OR22725 awarded by the U.S. Department of Energy. The government has certain rights in the described technologies.

### BACKGROUND

### Description of the Related Art

The smart grid concept has accelerated innovation in power grid systems by integrating and controlling each component of traditional power grid networks. However, these innovations have increased the number and variety of faults in the power grid signal. These faults in the power grid signals should be detected at an early stage. Otherwise, they can cause catastrophic problems, such as wildfire and long-term power, internet, and cellular network outages.

Although high-tech monitoring tools are available for power grid signals, conventional algorithms are unable to detect the characteristic behavior of power grid anomalies. Examples of such conventional algorithms are fast Fourier transform (FFT), amplitude-phase (AP), and power spectral density (PSD). Although it is possible to achieve some of the characteristics of the power grid signal using these conventional approaches, they do not consider the possibility of any changes in the statistical properties of the signal. Due to anomalies in the power grid, the statistical information of the power grid signal can change over time.

Conventional algorithms are weak in extracting the main characteristics of anomalies in the power grid. These weaknesses decrease the performance of detection and classification of faults in the power grid systems.

### SUMMARY

The present disclosure concerns implementing systems and methods for operating a power grid-based system, comprising: determining, by the processor, a spectral correlation function for a power grid signal being monitored; applying, by the processor, a trained classification model to the spectral correlation function, the trained classification model comprising a machine learning model trained to classify power grid signals based on power grid signal distortions; assigning, by the processor, a power grid distortion classification to the power grid signal based on an output of the trained classification model; and controlling an operation of an electrical device of the power grid-based system based on the power grid distribution classification.

The present disclosure concerns a system comprising: a processor; and a non-transitory computer-readable storage medium comprising programming instructions that are configured to cause the processor to implement a method for operating a power grid-based system. The programming instructions comprise instructions to: determine a spectral correlation function for a power grid signal being monitored; apply a trained classification model to the spectral correlation function, the trained classification model comprising a machine learning model trained to classify power grid signals based on power grid signal distortions; assign a power grid distortion classification to the power grid signal based on an output of the trained classification model; and control operation(s) of an electrical device of the power grid-based system based on the power grid distribution classification.

### BRIEF DESCRIPTION OF THE DRAWINGS

The present solution will be described with reference to the following drawing figures, in which like numerals represent like items throughout the figures.

FIG. 1 provides a block diagram illustration of the SCF-based detection for power grid signal distortion.

FIGS. 2A-2D (collectively referred to as “FIG. 2”) provide graphs showing magnitudes of SCF versus cyclic frequencies for 4 types of signature power grid signal distortions.

FIGS. 3A-3D (collectively referred to as “FIG. 3”) provide graphs showing normalized SCF magnitude for four distortion types as a function of frequency f and cyclic frequency a.

FIGS. 4A-4E (collectively referred to as “FIG. 4”) provide graphs showing comparison of the disclosed SCF-based method with conventional feature-extraction techniques using the t-SNE dimensional reduction algorithm. The color of a circle indicates the type of disturbance. Filled red circle marker (●): Arcing jumper; Orange circle marker (∘): Blown fuse; Green triangle (Δ): Line switching; Blue plus marker (+): Low-amplitude arcing; Magenta square marker (□): Transformer energization.

FIG. 5 provides a block diagram of SCF-based detection and classification system for power grid signal distortions.

FIGS. 6A-6B (collectively referred to as “FIG. 6”) show the confusion matrix results of the designed SCF-based detection and classification model for power grid signal distortions, considering two different signal-to-noise ratios.

FIG. 7 provides an illustration showing trigger-based fault detection algorithms.

FIG. 8 provides an illustration showing an ML-based fault detection and classification algorithms.

FIG. 9 provides a high-level diagram of SCF-based detection and classification technique for power grid signal distortions.

FIG. 10 provides a block diagram of an illustrative system implementing the present solution.

FIG. 11 provides a more detailed block diagram of the spectral correlation function determination module of FIG. 10.

FIG. 12 provides a flow diagram of an illustrative method for controlling a power grid system and/or monitoring circuit.

FIG. 13 provides a flow diagram of an illustrative method determining a spectral correlation function.

FIG. 14 provides a block diagram of a computing device.

### DETAILED DESCRIPTION

A novel method is essential to extract the main characteristic behavior of anomalies, considering changing statistical information. Thus, a spectral correlation function (SCF)-based algorithm has been developed that can obtain statistical changes over time to provide the primary characteristic behavior of power grid anomalies for detection and classification.

In practical systems, the signals include a non-stationary signal whose statistical properties and spectral contents vary with time. As conventional methods cannot provide the characteristic behavior of these changes, the periodicity of these changes is obtained with a cyclostationary signal processing technique to extract the characteristic feature of the non-stationary signal because cyclostationary signals exhibit hidden periodicities in the frequency domain that reveal a distinctive signal signature and allow for adequate classification. As electrical anomalies in grid systems typically exhibit cyclostationary behavior, a specific kind of non-stationarity is characterized by periodic fluctuations in statistical properties. For this reason, spectral correlation density can be beneficial in determining the cyclostationary behavior of these signals. Thus, a spectral correlation function (SCF) is crucial in detecting and extracting features of power grid signal distortions.

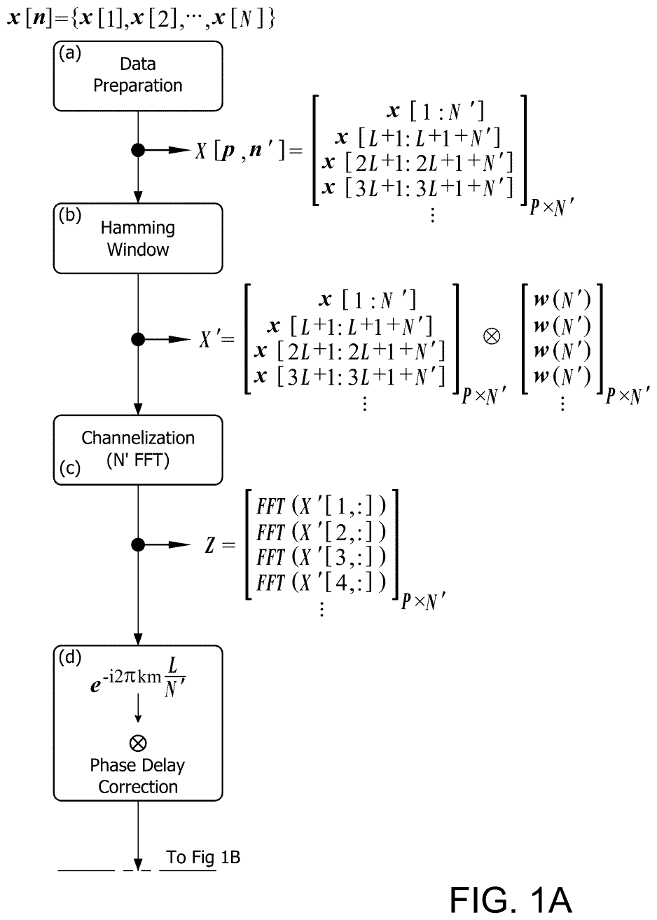

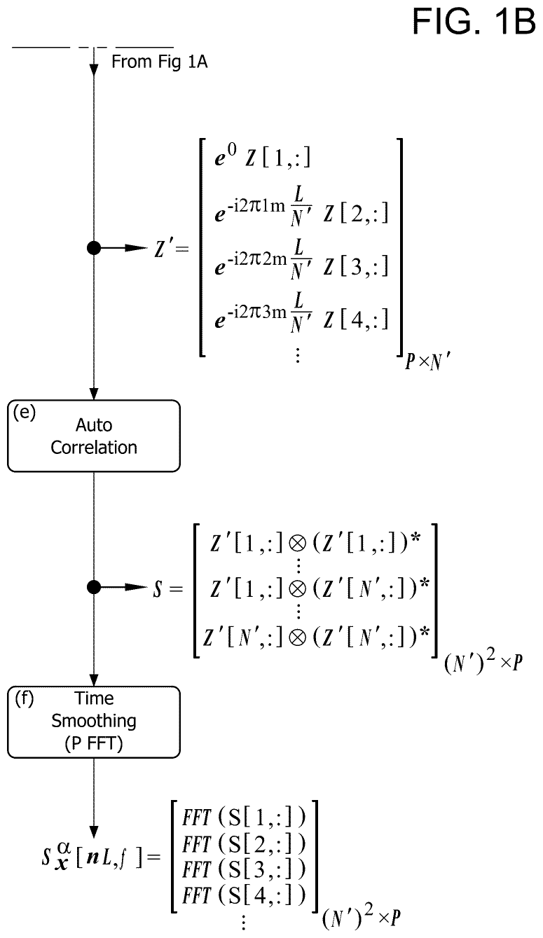

An example of an SCF-based detection algorithm for power grid signal distortions is shown in FIG. 1.

To express working principles of the disclosed algorithm, the mathematics of each algorithm step is described below. First, a power signal model is designed by considering the power grid signal distortions within a specific range as shown by mathematical equation (1).

$$x ( t ) = h ( t ) \text{?} s ( t ) + w ( t ) + ξ ( t ) , 0 \leq t \leq {t}_{T} \qquad ( 1 )$$

where s(t)=A cos(2πf₀t+φ) is an ideal current signal model with amplitude A, fundamental frequency f₀, and phase φ; h(t) indicates the impulse response of the power line; w(t) denotes an additive ambient noise; [symbol] stands for the convolution operation; and ξ(t) represents a random process characterizing the distortion signal that arises prior to time t_{T}. The disclosed SCF-based detection algorithm is processed by assuming that the relevant signal x(t) can be accessed.

### Background of Spectral Correlation Function

Analyzing the signal according to its specific type is essential for identifying its characteristic features. Conventionally, spectral properties of distortions are analyzed using a power spectral density (PSD) approach, which involves evaluating the signal's power as a function of frequency. However, the PSD is limited to representing the stationary components of cyclostationary signals, which results in a loss of significant information when encountering signals that exhibit more stochastic distortions. Therefore, the SCF-based algorithm can be employed to characterize the cyclostationary property of various grid events and anomalies. By using the Fourier transform with the cyclic Wiener-Khinchine relation, the SCF of the power signal model (1) can be expressed as shown by mathematical equation (2).

$${ψ}_{x} ( α , f ) = {\int }_{- ∞}^{∞} {ψ}_{x} ( α , τ ) exp ( - j 2 π f τ ) d τ \qquad ( 2 )$$

where subscript x denotes the anomalous input signal, and ψₓ(α, τ) indicates a cyclic auto-correlation function, which is defined by considering x as periodic with period T as shown by mathematical equation (3).

$${ψ}_{x} ( α , τ ) = {lim}_{T \to ∞} \frac{1}{T} {\int }_{- T / 2}^{T / 2} x ( t + \frac{τ}{2} ) {x}^{*} ( t - \frac{τ}{2} ) exp ( - j 2 πα t ) dt \qquad ( 3 )$$

where α=k/T, with k∈ [symbol] , specifies a cyclic frequency, and t denotes a lag parameter.

### Disclosed Algorithm for Spectral Correlation Function

Since the computational complexity of mathematical equation (2) is relatively high, the FFT accumulation method (FAM) is utilized for the disclosed SCF-based method as shown in FIG. 1.

$${S}_{x}^{α} [ nL , {f}_{i} ] = {\sum }_{r} {X}_{{T}^{′}} [ rL , {f}_{k} ] {X}_{{T}^{′}}^{*} [ rL , {f}_{ℓ} ] exp ( - \frac{j 2 π rq}{P} ) \qquad ( 4 )$$

where n=1, 2, . . . , N, and α=αᵢ+qΔα. Herein, αᵢ=fₖ− [symbol] is a cycle frequency with its resolution

$$Δα = \frac{{f}_{s}}{{N}^{′}} ; {f}_{j} = \frac{{f}_{k} + {f}_{ℓ}}{2}$$

indicates a spectral frequency;

$${f}_{s} = \frac{1}{{T}_{s}}$$

specifies the sampling frequency; and the auxiliary function X_{T′}(·,·) stands for the spectral components of x[n]=x(nTₛ), which is obtained as shown by mathematical equation (5).

$${X}_{{T}^{′}} [ n , f ] = {\sum }_{r = {N}^{′} / 2}^{{N}^{′} / 2} a ( r ) x [ n - r ] exp ( - j 2 π ( n - r ) {fT}_{s} ) , \qquad ( 5 )$$

where N′ represents the length of channelization conducted by FFT which is hopped over the data blocks of L samples, a(r) indicates a data-tapering window in the length of T′=N′Tₛ, and

$$P = \frac{N}{L} .$$

As shown in FIG. 1, the disclosed SCF-based algorithm includes six steps: (a) data preparation, (b) Hamming windowing, (c) channelization, (d) phase-delay correction, (e) autocorrelation, and (f) time-smoothing.

Data Preparation. In the data preparation stage, to obtain the correlation between spectral components of the signal in the next steps, a discrete-time signal model, given in mathematical equation (1), is defined as x[n]=x(nTₛ), where n=1, 2, . . . , N, and then transformed into matrix form based on the channelization length N′ and the length of the hoping block as X[p,n′]=x[n′+p(L−1)], where n=1, 2, . . . , N′ and p=1, 2, . . . , P. For the case N< (P−1)L+N′, zero-padding can be applied to x[n].

Hamming Windowing. To decrease spectral leakage between each channel, the prepared data is tapered as \tilde{X}=X⊗W, where W is a P×N′ data tapering matrix whose rows include a N′—length Hamming window a(n), and ⊗ denotes the Hadamard product.

Channelization. To obtain the frequency domain of each decomposed data, the channelization process is performed with FFT operation [symbol] {·} on each row of \tilde{X} as Ω[p,:]= [symbol] {\tilde{X}(p,:)}.

Phase Delay Correction. The phase delay due to the FFT operation is corrected employing phase delay correction as shown by mathematical equation (6).

$$Z [ p , {n}^{′} ] = Ω [ p , {n}^{′} ] exp ( - j 2 π ( p - 1 ) ( {n}^{′} - 1 ) ( \frac{L}{{N}^{′}} ) ) \qquad ( 6 )$$

Auto-Correlation. To obtain the correlation of each decomposed channel, the auto-correlation operation is applied between columns. The auto-correlation operation may be defined by mathematical equation (7).

$$\tilde{Z} [ : , ( {n}^{′} - 1 ) {N}^{′} + k ] = Z [ : , {n}^{′} ] ⊗ {Z}^{*} [ : , k ] , ∀ k = 1 , 2 , … , {N}^{′} \qquad ( 7 )$$

$$where \tilde{Z} ∈ {ℂ}^{P \times {( {N}^{′} )}^{2}} .$$

Time-smoothing. To improve the resolution of SCF, the P vectors with complex numbers are transformed again by applying a second FFT operation at final stage as

$${S}_{x}^{α} [ : , i ] = ℱ \{ \tilde{Z} [ : , i ] \} ,$$

where i=1, 2, . . . , (N′)². In the following section, results are provided through the normalized magnitude of SCF, which is obtained as

$$S = \vert {S}_{x}^{α} \vert / max ( {S}_{x}^{α} )$$

### Case Study by Using Developed Algorithm

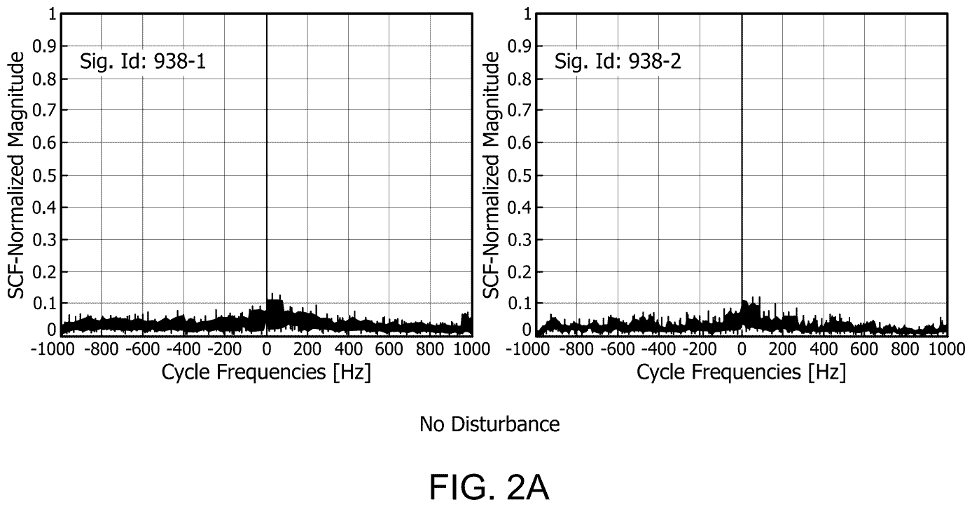

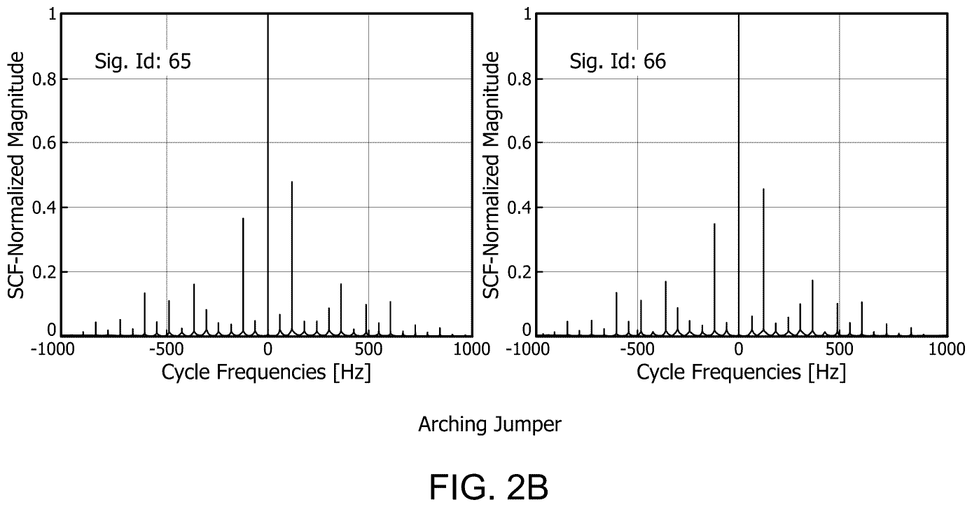

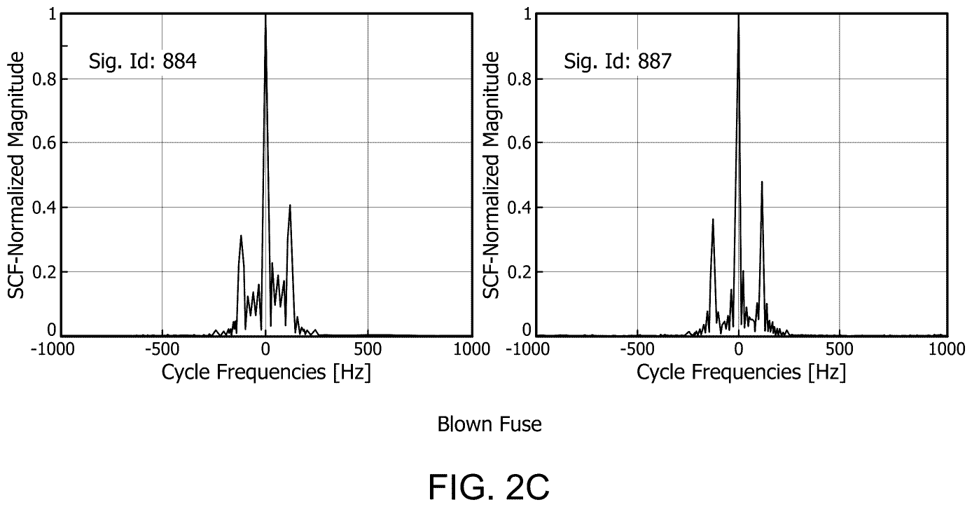

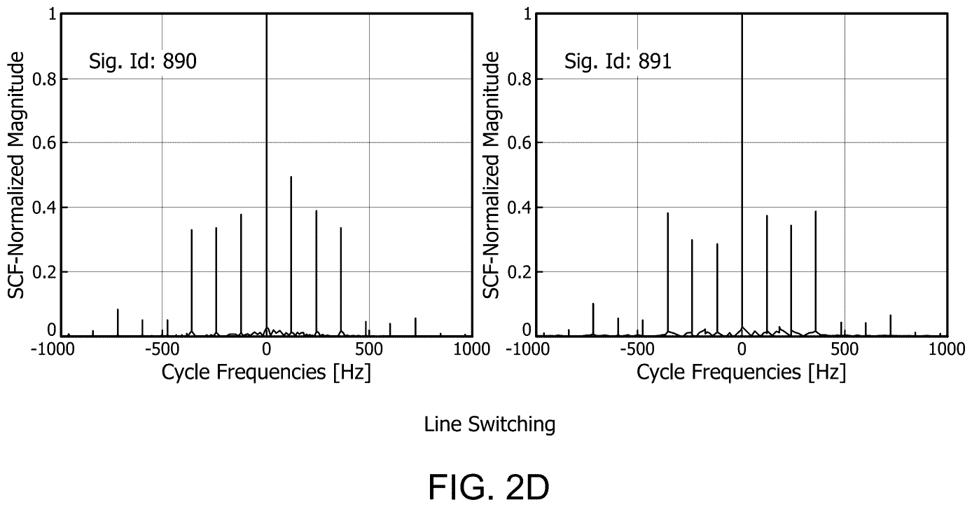

Real data from a grid event signature library (GESL) are used to validate the SCF-based detection algorithm. In particular, the GESL repository provides examples of no-disturbance (938), arcing-jumper (65 and 66), blown-fuse (884 and 887), and line-switching (890 and 891) events, with the indicated event IDs. The anomaly parts in each signal are obtained and examined to extract characteristic features. As there is no faulty region in the noise-containing signal, the real-world data is analyzed by taking two specific different numbers of samples from different parts of the signal. Therefore, examined signals are expressed as 938-1 and 938-2 in FIG. 2A for the no disturbance case.

Examples with no fault represent signals affected only by noise and serve as a reference in the analysis. Since the effect of the distortion can be observed more clearly in the current signal, each real-world data's current signal is used in all analyses.

FIGS. 2B-2D shows results of the disclosed SCF-based method for various types of distortions. They reveal that each type has a unique set of prominent cycle-frequency magnitudes. The reference signal (no-disturbance) does not exhibit cyclostationary characteristics, therefore, peaks are not observed at cycle frequencies. The present approach readily distinguishes among events, causing us to use it as an event classifier.

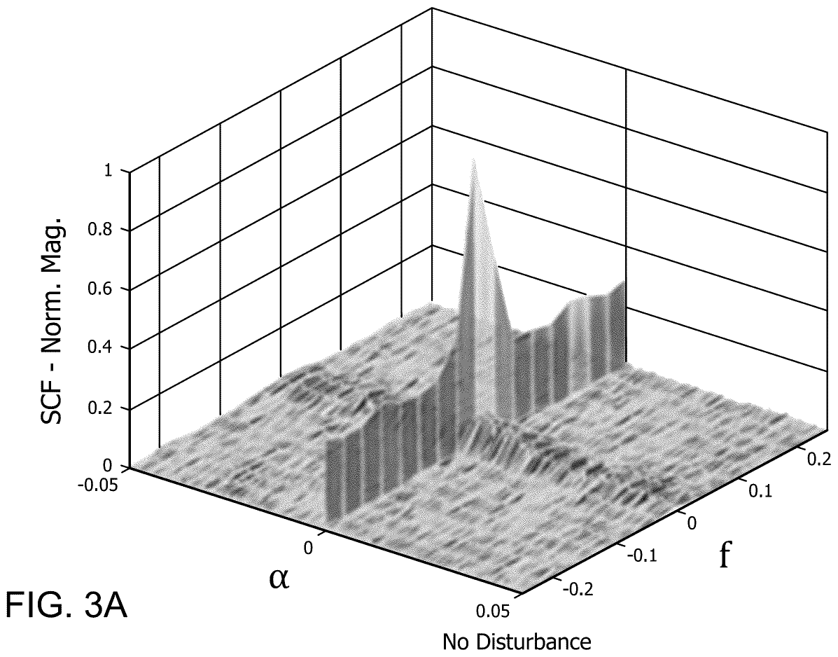

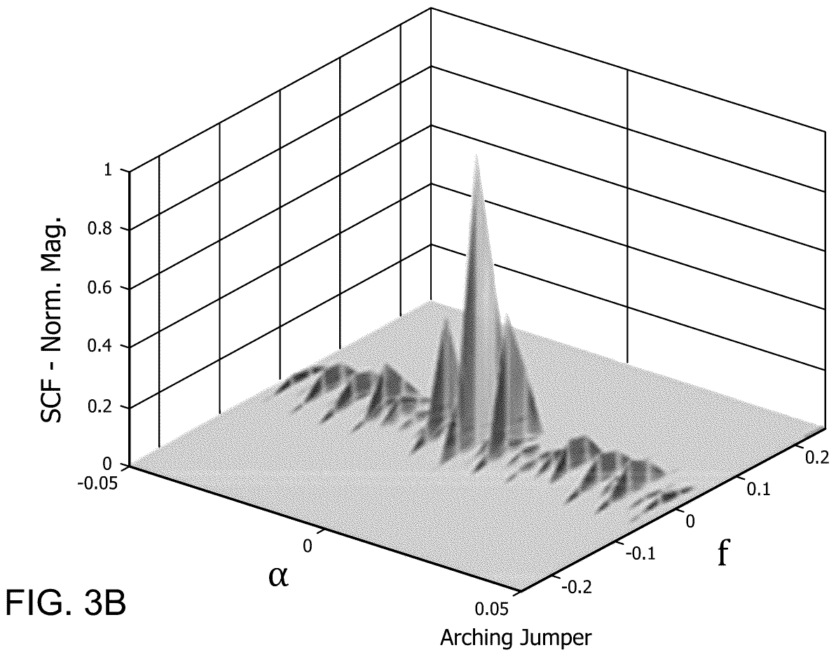

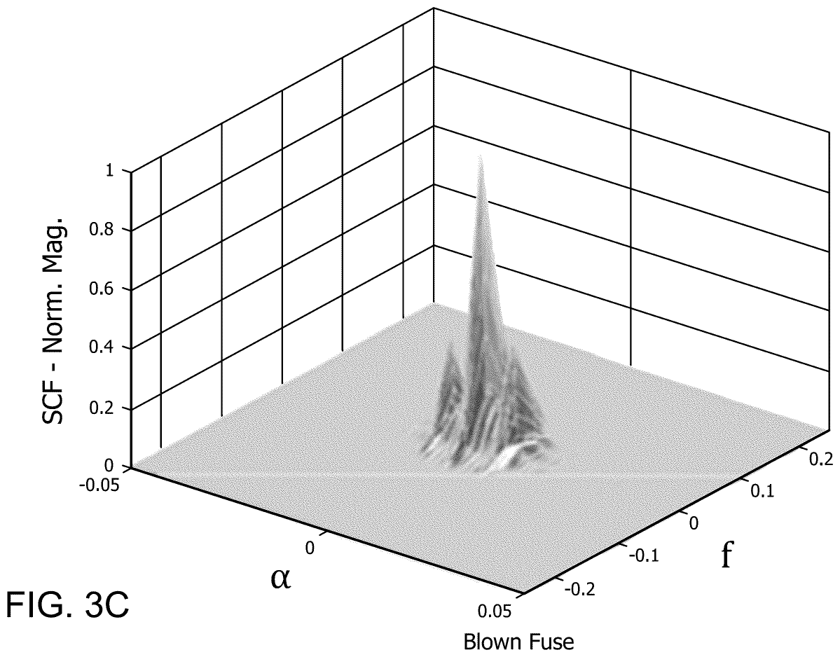

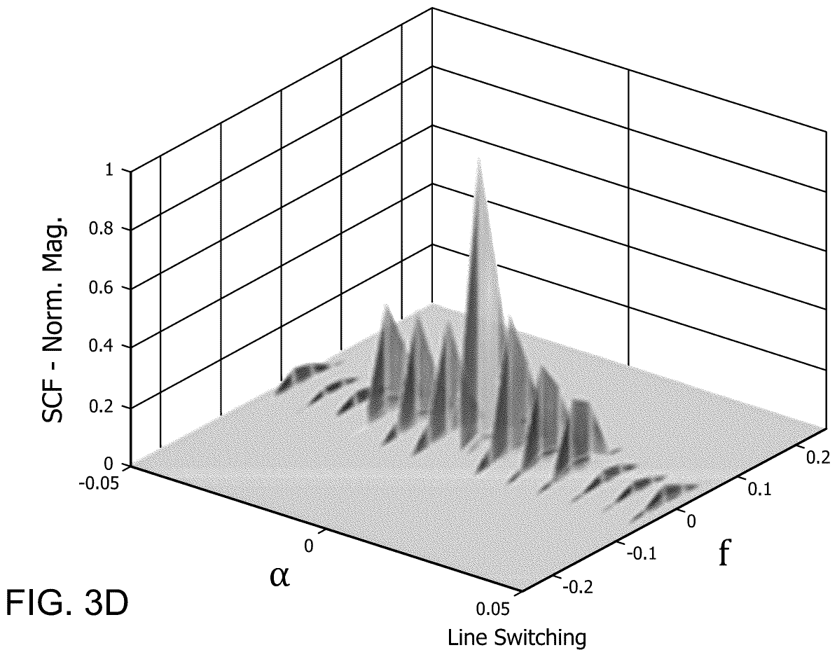

To further illustrate the advantages of the disclosed method, FIG. 3 shows plots of normalized magnitude of SCF against the normalized frequency f and the normalized cyclic frequency a.

These results show that cyclostationary signals have multiple periodic hidden cyclic frequencies. Noise signals, which lack cyclostationarity, have no such periodicity. Arcing-jumper events exhibit a dependence on cyclic frequency reminiscent of a sinc-squared function. A blown fuse, on the other hand, corresponds to power concentrated in cyclic frequencies around 0 Hz. At the same time, the average magnitudes of the line switching are higher than those resulting from other types of power grid signal distortions.

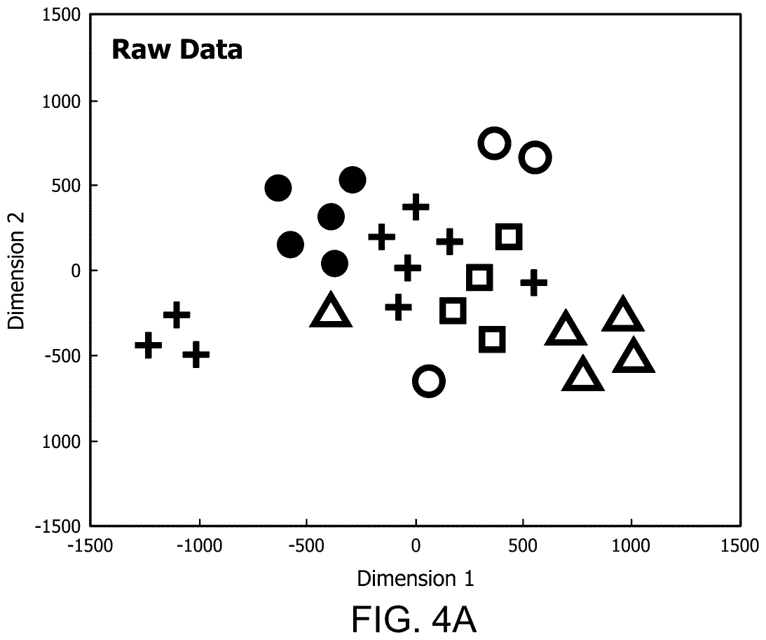

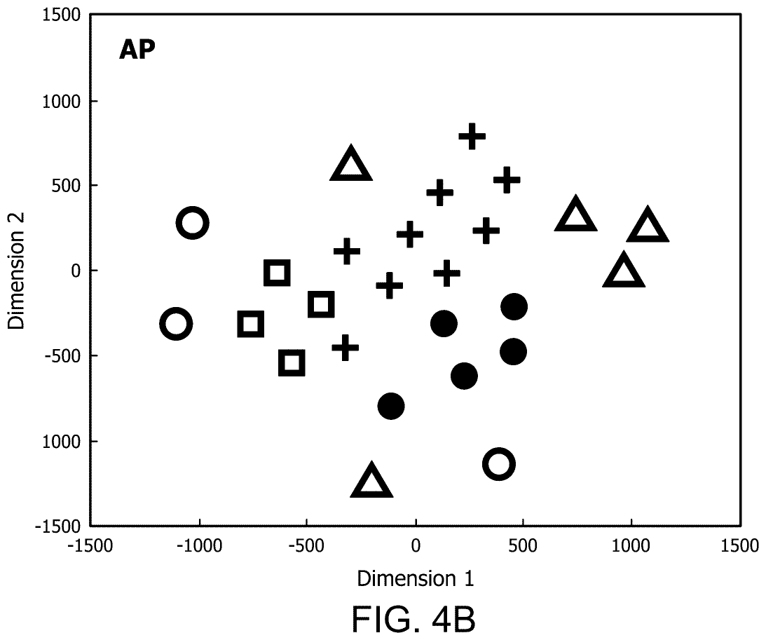

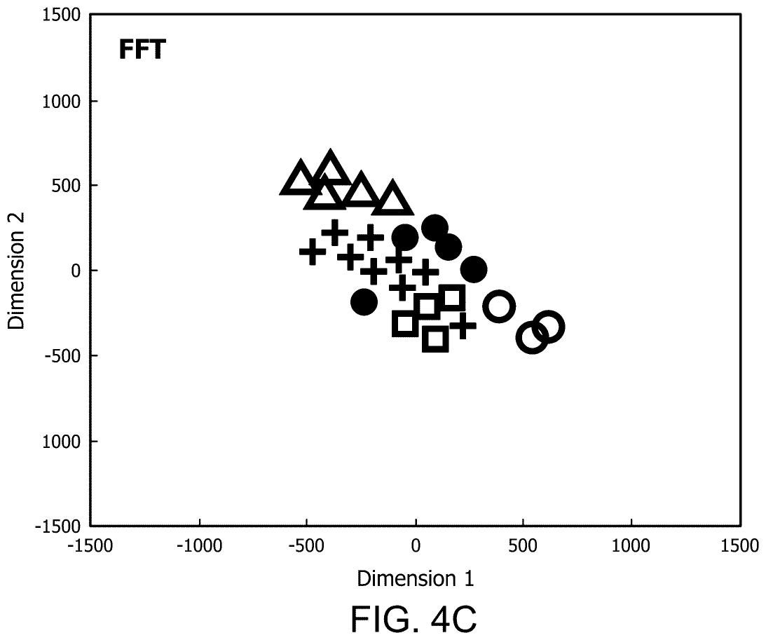

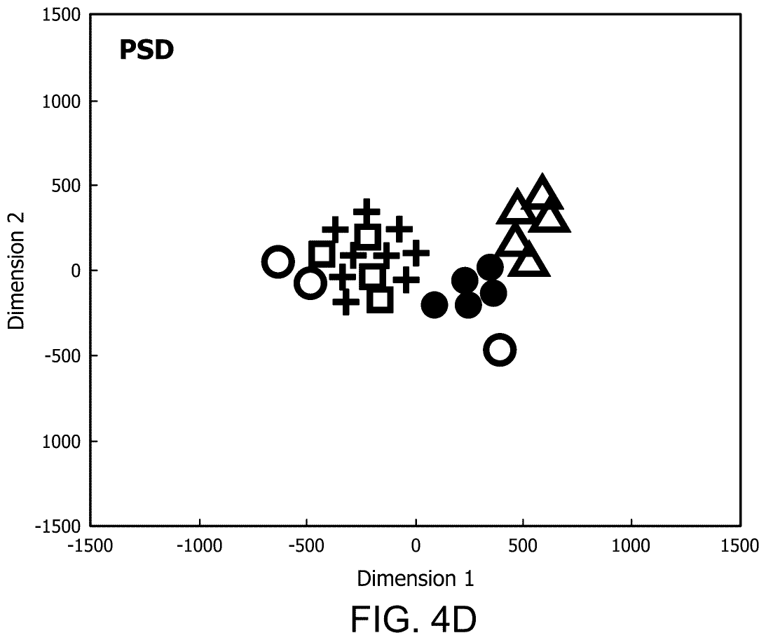

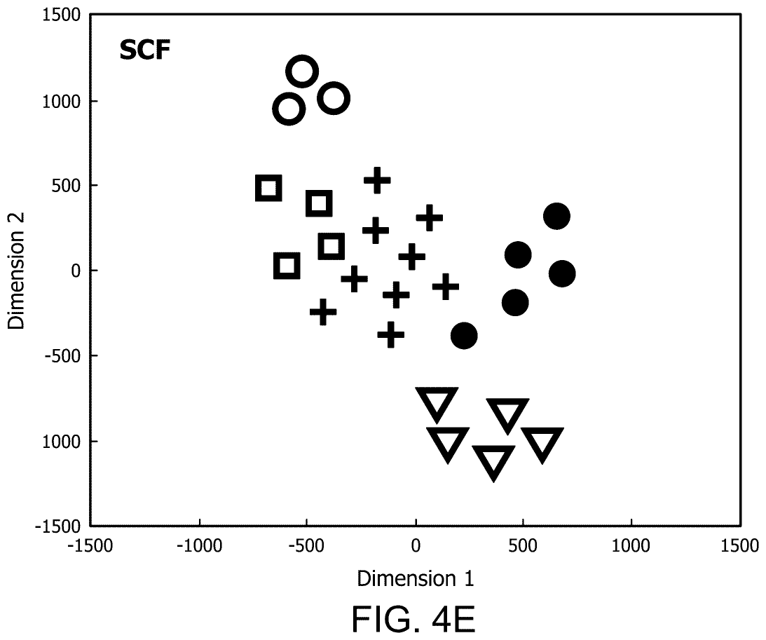

The disclosed method reveals distinctive characteristics of various types of power grid signal distortions. To ensure consistency of results and validate its effectiveness, the proposed SCF-based approach was applied to multiple sets of real data exhibiting the same types of signal distortions. The t-Distributed Stochastic Neighbor Embedding (t-SNE) high-dimensional data visualization algorithm demonstrates that the disclosed technique groups grid-signal disturbances by type. Hence, in FIG. 4, t-SNE is employed to compare the disclosed SCF-based signal-detection and feature extraction method with conventional methods such as raw data, amplitude and phase (AP), FFT, and PSD.

The t-SNE enables visualization of high-dimensional data in a lower-dimensional space, typically by utilizing only two or three dimensions, while preserving the pairwise similarities between the data points as much as possible. This technique evaluates power grid signal distortions by examining the position of each data point in a two-dimensional plane. The implementation of this process involves utilizing the repositories mentioned above to acquire real-world data for each type of event. The results show that the FFT, a prevalent technique for feature extraction, causes points corresponding to different events to be distributed without forming distinct clusters on the plot. In contrast, the features obtained from the SCF-based method are appropriately grouped.

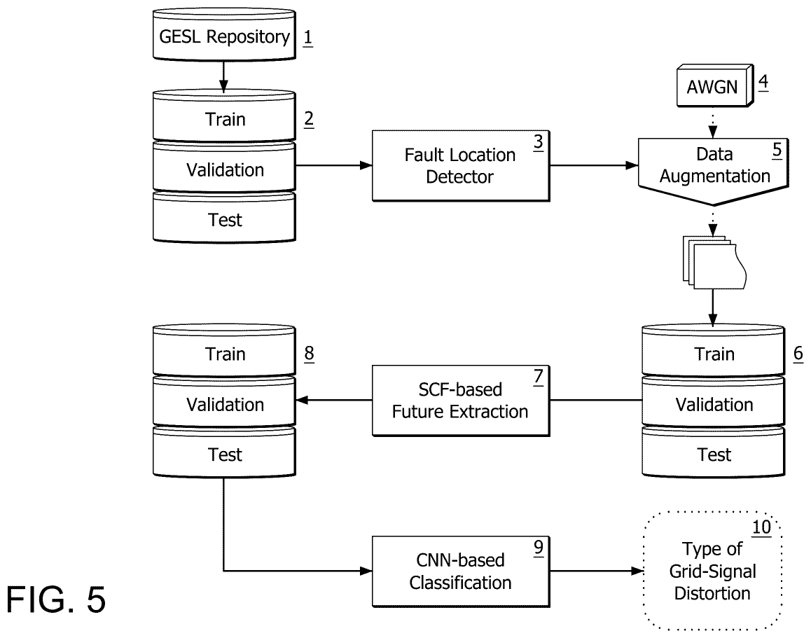

The real-world signatures were used to illustrate the performance achievement of SCF-based feature extraction in detecting and classifying power grid signal distortions. FIG. 5 shows a machine learning (ML)-based process developed to perform SCF-based feature extraction for detecting and classifying power grid signal distortions.

The real-world data for each signature is collected from the GESL repository 1 to create train, validation, and test datasets 2. At the beginning of the disclosed process, training and test data are separated randomly to ensure an accurate assessment of the disclosed process' performance. Herein, the train and validation datasets were created for the training process, and the test dataset was created to validate the performance of the disclosed technologies. To build a dataset with the interested region of the power grid signal that includes anomaly, a fault location detector 3 is employed to make a dataset. Since the number of data is insufficient for training and testing operations, the augmentation 5 process is applied by feeding additive white Gaussian noise (AWGN) 4 at different levels of signal-to-noise ratio (SNR) 6. Subsequently, the collected dataset is fed into the SCF-based feature extraction method 7 to obtain the main characteristic feature of each signature. Finally, a convolutional neural network (CNN)-based ML model 9 is trained and tested with the achieved feature set 8. The trained ML model can be used as part of a classification process to determine the type of power grid signal distortion 10, e.g., arcing jumper, blown fuse, switching, low amplitude arcing, and transformer energization. The input of the model was prepared using an SCF-based feature extraction method to obtain the model's actual performance.

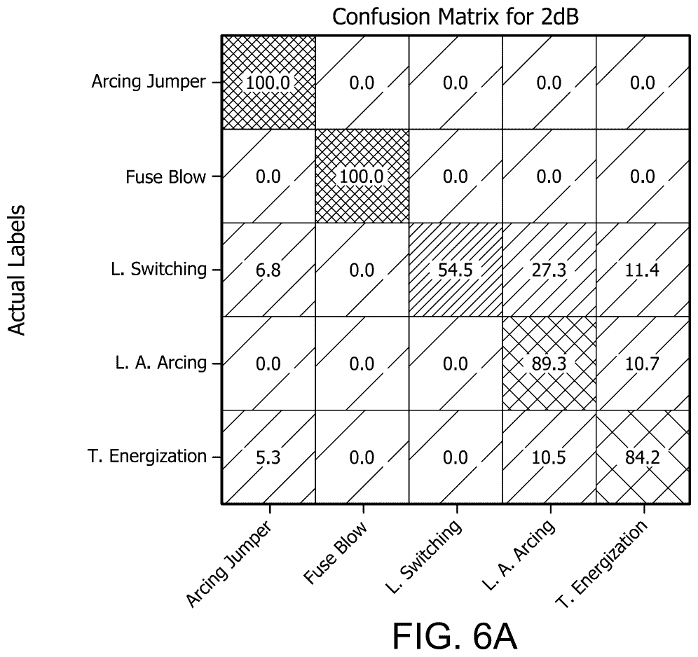

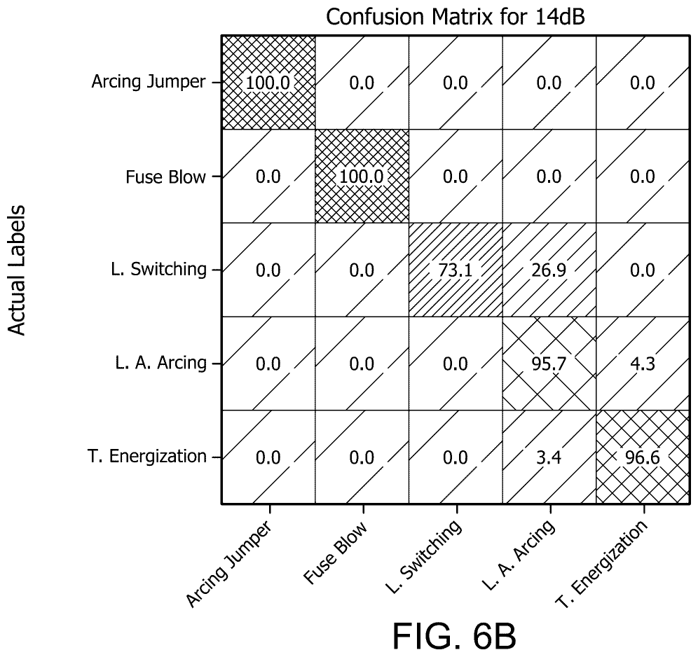

Since measurement tools in power grid systems can yield unpredictable noise, the SNR of the recorded real-world power signals can vary. Therefore, the trained ML model was tested with different SNR values, such as 2 dB and 14 dB. The classification performance is presented with the confusion matrix in FIG. 6.

It is noted here that the SNR of the average power signal is typically around 30 db. So, even though the SNR values of the test signal were low, the results reveal an excellent classification performance because the SCF-based feature extraction is not affected by noise. Consequently, an excellent performance of SCF-based detection and classification methods was developed for power grid signal distortion.

### Potential Benefits

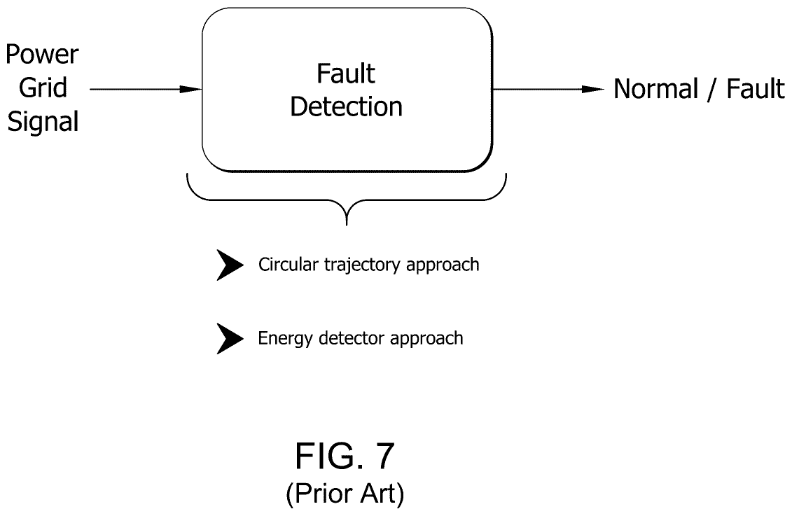

Conventional methods of detecting distortion in power grid systems are through trigger-based techniques that indicate whether the grid signal includes anomalies, as shown in FIG. 7.

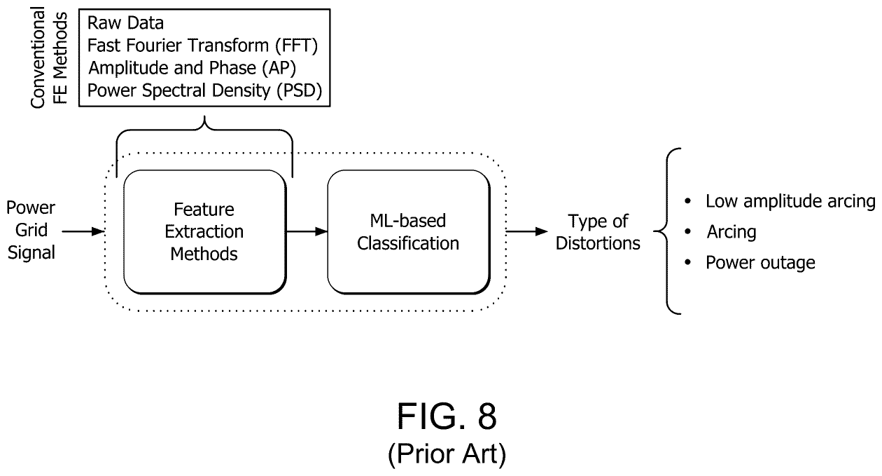

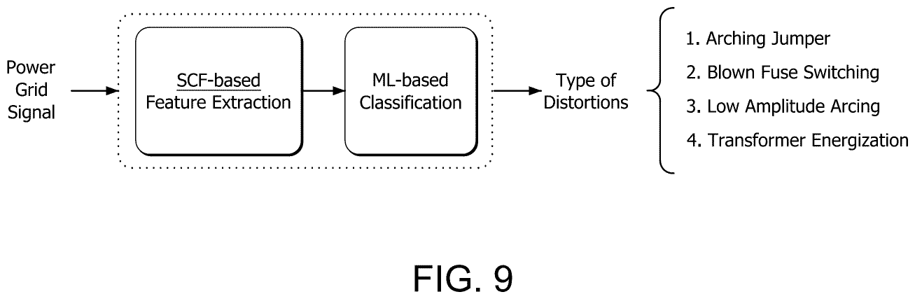

These conventional algorithms address only a limited number of anomaly types despite power grid systems encountering a wide variety of distortions, including arcing jumper, blown fuse, line switching, and transformer energization. This limitation stems from the need for more feature extraction techniques that can effectively capture the unique characteristics of power grid signal distortions. Currently, conventional feature extraction techniques, e.g., AP, FFT, and PSD, as noted in FIG. 8, are used to determine specific information about examined signals, such as signals' amplitude, phase, and frequency changes or relations.

This can enhance the accuracy of the classification of various types of events in power grid systems. As the way of detecting multiple types of event signatures is provided by the disclosed technologies, a fast treatment of the power grid system can be applied to avoid catastrophic problems, such as wildfires and power outages.

### Potential Commercial Applications

The disclosed technologies can be used in fields such as energy. More specifically, electric utility companies can use the disclosed methods to remote control into, and condition, monitoring units. Also, they could be adopted by the electric utility companies to avoid natural disasters, which would happen due to anomalies in the power grid.

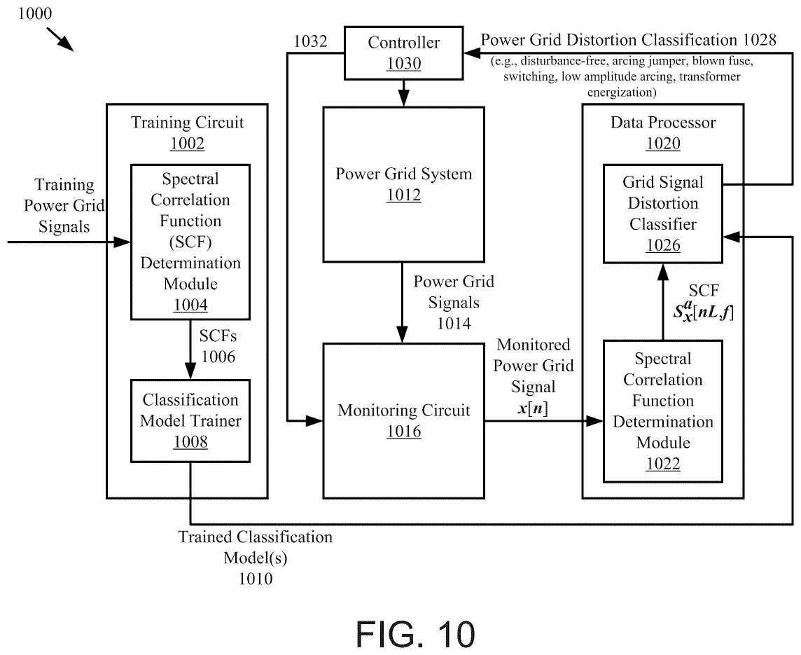

FIG. 10 provides a block diagram of an illustrative system 1000 implementing the present solution. System 1000 comprises a power grid system 1012. Any known or to be known power grid system can be used here. For example, the power grid system 1012 may comprise a power grid network of interconnected electrical transmission lines, power plants, and substations that generate, transmit and distribute electricity from producers to consumers across a geographic area. The electricity may be delivered to homes and/or businesses.

Components of the power grid system 1012 may be monitored by a monitoring circuit 1016 and/or have operations that are controlled by controller 1030. Power grid signals 1014 are monitored by monitoring circuit 1016. The power grid signals 1014 may comprise non-stationary signals whose statistical properties and spectral content vary with time. The non-stationary signals can include, but are not limited to, current signals. Parameters of the power grid system's components may be controlled based on statistical changes in the monitored power grid signals over time. These parameters include, but are not limited to, inertia (e.g., to maintain stability), voltage (e.g., to regulate power level), frequency (e.g., to provide consistent flow of electricity), thermal (e.g., to manage heat generation), armature rotational speed, tap changer settings on transformers, capacitor back switching, voltage regulator adjustments, and/or resistance of a variable resistor.

During operations, monitoring circuit 1016 provides a monitored power grid signal x[n] to a data processor 1020. Data processor 1020 comprises a spectral correlation function (SCF) determination module 1022 and a grid signal distortion classifier 1026. SCF determination module 1022 is generally configured to (i) receive the monitored power grid signal x[n] from the monitoring circuit 1016, and (ii) determine a spectral correlation function (SCF) for the received monitored power grid signal x[n]. SCF may be defined by

$${S}_{x}^{α} [ nL , f ] .$$

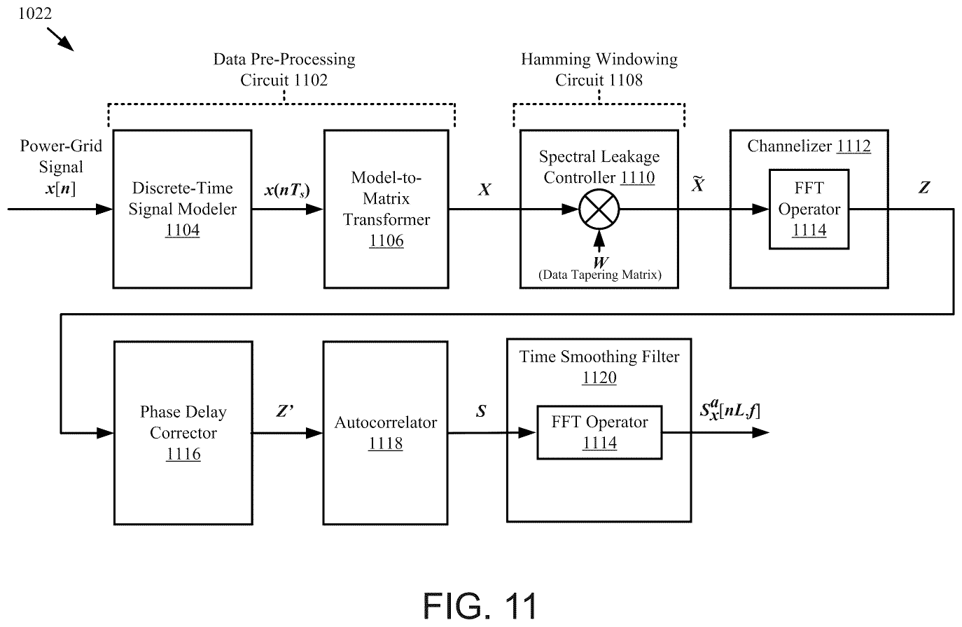

The manner in which SCF is generated will be discussed below in detail in relation to FIG. 11.

SCF is provided to grid signal distortion classifier 1026 to facilitate detection and extraction of features of power grid signal distortions. Grid signal distortion classifier 1026 is configured to access trained classification model(s) 1010 and apply the same to the received SCF to facilitate classification of the monitored power grid signal x[n] as being disturbance-free or as having one of a plurality of disturbance types. The trained classification model(s) 1010 may be configured (i) receive or obtain features of power grid signal distortion using the SCF, (ii) obtain a power grid distortion classification based on the features of power grid signal distortion and/or type(s) of disturbance(s), and/or (iii) assign the power grid distortion classification to a respective power grid signal x[n] and/or component of the power grid system associated with the respective power grid signal x[n].

The power grid distortion classification 1028 and/or other information is passed to controller 1030 for use in controlling operations and/or parameters the power grid system 1012. The other information can include, but is not limited to, an identifier of the power grid signal x[n] and/or an identifier of the component of the power grid system associated with the power grid signal x[n]. The power grid distortion classification 1028 can include, but is not limited to, disturbance-free, arcing jumper, blown fuse, switching, low amplitude arcing, and/or transformer energization.

The power grid distortion classification 1028 and/or other information may also be passed to the monitoring circuit 1016 as shown by arrow 1032. Operations of the monitoring circuit 1016 may be controlled by controller 1030 based on the power grid distortion classification 1028 and/or other information. For example, the controller 1030 may instruct monitoring circuit 1016 to more frequently or less frequently monitor a power grid signal from a particular component of the power grid system, and/or output a notification indicating the power grid distortion classification 1028. The notification can be auditory, visual and/or tactile.

The classification model(s) 1010 may be trained by a training circuit 1002 using training power grid signals. The training power grid signals can include, but are not limited to, power grid signals known to be disturbance-free or have disturbances of predetermined types. The predetermined types of disturbances can include, but are not limited to, arcing jumper, blown fuse, switching, blown fuse, switching, low amplitude arcing, and/or transformer energization. The training circuit 1002 comprises an SCF determination module 1004 and a classification model trainer 1008. The operations of SCF determination model 1004 may be the same as or similar to those of SCF determination module 1022. The SCF(s) 1006 generated by the SCF determination model 1004 is (are) passed to the classification model trainer 1008 for training classification model(s).

The classification model(s) 1010 can include any known or to be known machine learning model(s). For example, one or more of the following machine learning models are employed here: supervised learning; unsupervised learning; semi-supervised learning; and reinforcement learning. In a supervised learning model, the model learns a function that maps an input (also known as feature or features) to an output (also known as target) during training with a labeled data set (or dataset). In an unsupervised learning model, the algorithm discovers patterns among data. In a semi-supervised model, the model learns a function that maps an input (also known as feature or features) to an output (also known as a target) during training with both labeled and unlabeled data. Such machine learning models can include, but are not limited to, a support vector machine classifier, a deep learning model, a convolutional neural network, and/or a statistical analyzer. These patterns or behaviors can then be used to dynamically classify power grid signal distortions.

FIG. 11 provides a more detailed block diagram of the SCF determination module 1022. SCF module 1022 comprises a data pre-processing circuit 1102, a hamming window circuit 1108, a channelizer 1112, a phase delay corrector 1116, an autocorrelator 1118, and a time smoothing filter 1120.

The data pre-processing circuit 1102 comprises a discrete-time signal modeler 1104 and a model-to-matrix transformer 1106. Discrete-time signal modeler 1104 performs operations to define a discrete-time signal model for power grid signal x[n]. The discrete-time signal model x(nTₛ) may be defined by above-provided mathematical equation (1). The discrete-time signal model facilitates a correlation between spectral components of the signal in subsequent operations. The discrete-time signal model x(nTₛ) is provided to the model-to-matrix transformer 1106 where it is transformed into a matrix X based on the channelization length N′ and the length of the hoping block.

Matrix X[p,n′] is passed to the hamming window circuit 1108. The hamming window circuit 1108 comprises a spectral leakage controller 1110 configured to decrease spectral leakage between each channel. This is achieved by tapering the data in matrix X. Matrix X is combined with a data tapering matrix W whose rows include an N′ length Hamming window a(n). The results of the data tapering comprise results of Hadamard product. Hadamard product is a binary operation that takes in two matrixes X and W of the same dimensions and returns a matrix \tilde{X} or X′ of multiplied corresponding elements.

Matrix \tilde{X} or X′ is passed to channelizer 1112. Channelizer 1112 performs operations to separate a signal into multiple data channels. In this regard, channelizer 1112 comprises an FFT operator 1114 to obtain a frequency-domain representation of the power grid signal. The frequency-domain representation can include information about the signal's magnitude and phase at each frequency. FFT operator 1114 performs an FFT operation F{·} on each row of matrix \tilde{X} or X′. The result of the FFT operation may be referred to as frequency-domain representation Z. The FFT operation causes phase delays which are corrected in block 1116. Phase delay corrector 1116 performs operations to adjust the time delays of a signal's frequency components. These operations may be defined by above-provided mathematical equation (6). The result of these operations may be referred to as a modified frequency-domain representation Z′.

The output Z′ of the phase delay corrector 1116 is provided to autocorrelator 1118. Autocorrelator 1118 applies element-wise multiplication between signals of each decomposed frequency channel and a delayed version of itself to obtain their statistical relations. These operations may be defined by the above-provided mathematical equation (7). The output S of the autocorrelator 1118 is passed to time smoothing filter 1120.

Time smoothing filter 1120 performs operations to improve resolution of the SCF. In this regard, time smoothing filter 1120 comprises an FFT operator 1114 that applies an FFT operation to S to obtain an SCF.

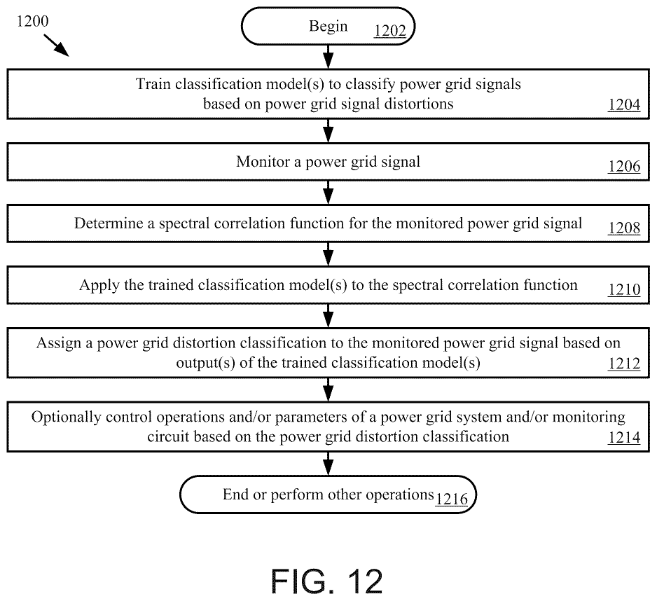

FIG. 12 provides a flow diagram of an illustrative method 1200 for controlling a power grid system (e.g., power grid system 1012 of FIG. 10) and/or monitoring circuit (e.g., circuit 1016 of FIG. 10). Method 1200 may be implemented by system 1000 of FIG. 10. Method 1200 may include more or less blocks and/or operations than that shown. For example, operations of block 1210 and 1212 may be combined into a single block.

Method 1200 begins at block 1202 and continues to block 1204 where classification model(s) is (are) trained to classify power grid signals based on power grid signal distortions. Any known or to be known technique for training machine learning model(s) can be used. For example, training circuit 1002 of FIG. 10 may perform operations in block 1204 to generate SCFs 1006 based on training power grid signals and use the SCFs 1006 to train classification model(s). It should be noted that the classification model(s) may continue to be trained after being deployed for power grid distribution classification.

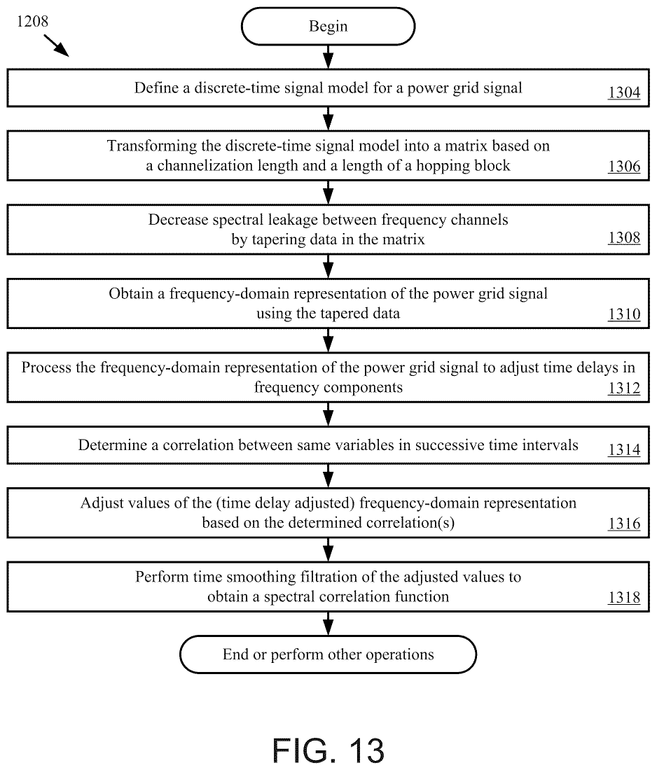

In next block 1206, a power grid signal (e.g., signal 1014 of FIG. 10) is monitored by a monitoring circuit (e.g., monitoring circuit 1016 of FIG. 10). A processor (e.g., data processor 1020 of FIG. 10) performs operations in block 1208 to determine an SCF for the monitored power grid signal. These operations will be discussed in detail below in relation to FIG. 13. The processor also performs operations in blocks 1210-1212 to: apply the trained classification model(s) to the SCF; and assign a power grid distortion classification to the monitoring power grid signal based on output(s) of the trained classification model(s). The assigned power grid distortion classification can include, but is not limited to, disturbance-free, arcing jumper, blown fuse, switching, low amplitude arcing, or transformer energization.

In optional block 1214, the processor and/or other device (e.g., controller 1030 of FIG. 10) controls operations and/or adjusts parameter(s) of the power grid system (e.g., power grid system 1012 of FIG. 10) and/or monitoring circuit based on the power grid distribution classification. For example, the controller 1030 may: instruct monitoring circuit 1016 to more frequently or less frequently monitor a power grid signal from a particular component of the power grid system; output a notification indicating the power grid distortion classification 1028; instruct component(s) of the power grid system 1012 to change an output voltage, change an output current, change a power level, change a frequency, change a rotational speed, change a transformer setting, actuate switches, enable capacity back switching, adjust parameters of a voltage regulator, and/or adjust a variable resistance. The notification can be auditory, visual and/or tactile. The parameters include, but are not limited to, inertia (e.g., to maintain stability), voltage (e.g., to regulate power level), frequency (e.g., to provide consistent flow of electricity), thermal (e.g., to manage heat generation), armature rotational speed, tap changer settings on transformers, capacitor back switching, voltage regulator adjustments, and/or resistance of a variable resistor. Subsequently, method 1200 continues to block 1216 where it ends or other operations are performed (e.g., return to block 1202).

FIG. 13 provides a flow diagram of method or process performed in block 1208 of FIG. 10. The method or process involves defining a discrete-time signal model for a power grid signal, as shown by block 1304. The discrete-time signal model may be defined as x[n]=x(nTₛ), where n=1, 2, . . . , N. In block 1306, the discrete-time signal model is transformed into a first matrix (e.g., matrix X of FIG. 11) based on a channelization length and a length of a hopping block. A spectral leakage between frequency channels is decreased in block 1308 by tapering data in the first matrix. A frequency-domain representation of the power grid signal is obtained in block 1310 using the tapered data. The frequency-domain representation of the power grid signal is processed in block 1312 to adjust time delays in frequency components. A correlation between same variables in successive time intervals is determined in block 1314. Values of the (time delay adjusted) frequency-domain representation are adjusted in block 1316 based on the determined correlation(s). Time smoothing filtration of the adjusted values is performed in block 1318 to obtain an SCF.

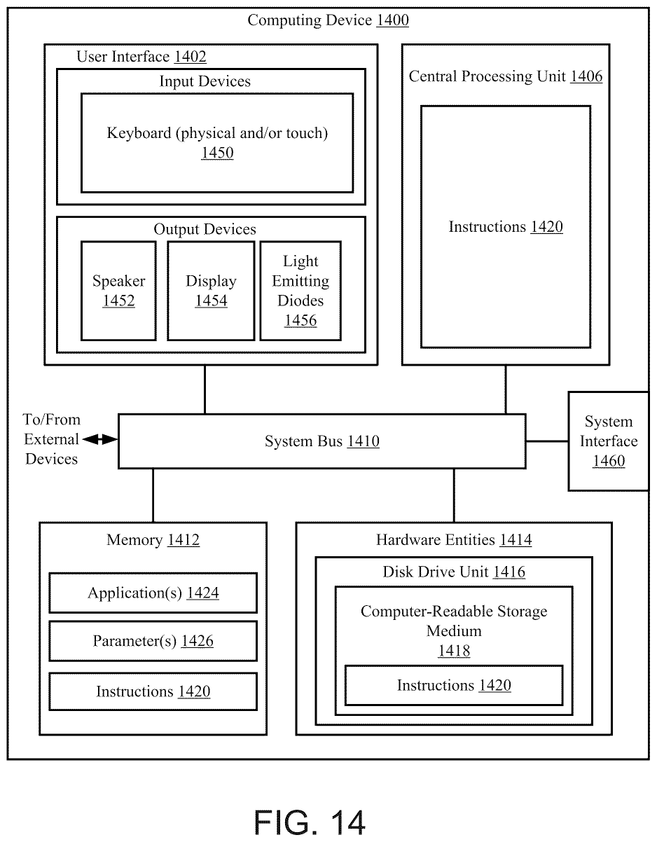

Referring now to FIG. 14, there is shown an illustrative architecture for a computing device 1400. Components 1002, 1004, 1008, 1012, 1016, 1020, 1022, 1026, 1030 of FIG. 10 and/or components 1104, 1106, 1110, 1014, 1116, 1018, 1114 of FIG. 11 is/are the same as or similar to computing device 1400. As such, the discussion of computing device 1400 is sufficient for understanding the listed components of FIG. 10 and/or FIG. 11.

Computing device 1400 may include more or less components than those shown in FIG. 14. However, the components shown are sufficient to disclose an illustrative solution implementing the present solution. The hardware architecture of FIG. 14 represents one implementation of a representative computing device configured to receive information, process the receive information, transmit information and/or control operations of one or more robots, as described herein. As such, the computing device 1400 of FIG. 14 implements at least a portion of the method(s) described herein.

Some or all components of the computing device 1400 can be implemented as hardware, software and/or a combination of hardware and software. The hardware includes, but is not limited to, one or more electronic circuits. The electronic circuits can include, but are not limited to, passive components (e.g., resistors and capacitors) and/or active components (e.g., amplifiers and/or microprocessors). The passive and/or active components can be adapted to, arranged to and/or programmed to perform one or more of the methodologies, procedures, or functions described herein.

As shown in FIG. 14, computing device 1400 comprises a user interface 1402, a Central Processing Unit (CPU) 1406, a system bus 1410, a memory 1412 connected to and accessible by other portions of computing device 1400 through system bus 1410, a system interface 1460, and hardware entities 1414 connected to system bus 1410. The user interface can include input devices and output devices, which facilitate user-software interactions for controlling operations of the computing device 1400. The input devices include, but are not limited to, a physical and/or touch keyboard 1450. The input devices can be connected to the computing device 1400 via a wired or wireless connection (e.g., a Bluetooth® connection). The output devices include, but are not limited to, a speaker 1452, a display 1454, and/or light emitting diodes 1456. System interface 1460 is configured to facilitate wired or wireless communications to and from external devices (e.g., network nodes such as access points, etc.).

At least some of the hardware entities 1414 perform actions involving access to and use of memory 1412, which can be a random access memory (RAM), a disk drive, flash memory, a universal serial bus (USB) drive and/or another hardware device that is capable of storing instructions and data. Hardware entities 1414 can include a disk drive unit 1416 comprising a computer-readable storage medium 1418 on which is stored one or more sets of instructions 1420 (e.g., software code) configured to implement one or more of the methodologies, procedures, or functions described herein. The instructions 1420 can also reside, completely or at least partially, within the memory 1412 and/or within the CPU 1406 during execution thereof by the computing device 1400. Memory 1412 and the CPU 1406 also can constitute machine-readable media. The term “machine-readable media”, as used here, refers to a single medium or multiple media (e.g., a centralized or distributed database, and/or associated caches and servers) that store the one or more sets of instructions 1420. The term “machine-readable media”, as used here, also refers to any medium that is capable of storing, encoding or carrying a set of instructions 1420 for execution by the computing device 1400 and that cause the computing device 1400 to perform any one or more of the methodologies of the present disclosure.

In view of the forgoing, the present solution concerns implementing systems and methods (e.g., method 1200 of FIG. 12) for operating a power grid-based system (e.g., system 1000 of FIG. 10). The methods comprise: training one or more classification models to classify power grid signals based on power grid signal distortions; determining, by the processor (e.g., data processor 1020 of FIG. 1), a spectral correlation function for a power grid signal being monitored (e.g., signal x[n] of FIG. 10); applying, by the processor, a trained classification model (e.g., trained classification model 1010 of FIG. 10) to the spectral correlation function (wherein the trained classification model comprises a machine learning model trained to classify power grid signals based on power grid signal distortions); assigning, by the processor, a power grid distortion classification (e.g., classification 1028 of FIG. 10) to the power grid signal based on an output of the trained classification model; and/or controlling operation(s) of an electrical device of the power grid-based system based on the power grid distribution classification. The assigned power grid distortion classification can include, but is not limited to, disturbance-free, arcing jumper, blown fuse, switching, low amplitude arcing, or transformer energization.

The electrical device can include, but is not limited to, a power grid system, a component of the power grid system, or a monitoring circuit monitoring power signals of the power grid signal. The controlling may comprise: instructing a monitoring circuit to more or less frequently monitor a power grid signal from a particular component of the power grid-based system; and/or instructing a component of the power grid-based system to change an output voltage, change an output current, change a power level, change a frequency, change a rotational speed, change a transformer setting, actuate a switch, enable capacity back switching, adjust a parameter of a voltage regulator, and/or adjust a variable resistance.

The spectral correlation function may be determined by: defining a discrete-time signal model for a power grid signal; transforming the discrete-time signal model into a matrix based on a channelization length and a length of a hopping block; decreasing a spectral leakage between frequency channels by tapering data in the matrix; obtaining a frequency-domain representation of the power grid signal using the tapered data; processing the frequency-domain representation of the power grid signal to adjust time delays in frequency components; determining a correlation between same variables in successive time intervals; adjusting values of the frequency-domain representation based on the determined correlation; and/or performing time smoothing filtration of the adjusted values to obtain the spectral correlation function.

The present document also concerns a system comprising: a processor; and a non-transitory computer-readable storage medium comprising programming instructions that are configured to cause the processor to implement a method for operating a power grid-based system. The programming instructions comprise instructions to: train one or more classification models to classify power grid signals based on power grid signal distortions; determine a spectral correlation function for a power grid signal being monitored; apply a trained classification model to the spectral correlation function (the trained classification model comprising a machine learning model trained to classify power grid signals based on power grid signal distortions); assign a power grid distortion classification to the power grid signal based on an output of the trained classification model; and control an operation of an electrical device of the power grid-based system based on the power grid distribution classification. The assigned power grid distortion classification can include, but is not limited to, disturbance-free, arcing jumper, blown fuse, switching, low amplitude arcing, or transformer energization.

The electrical device can include, but is not limited to, a power grid system, a component of the power grid system, or a monitoring circuit monitoring power signals of the power grid signal. The operation of an electrical device may be controlled for example, by: instructing a monitoring circuit to more or less frequently monitor a power grid signal from a particular component of the power grid-based system; and/or instructing a component of the power grid-based system to change an output voltage, change an output current, change a power level, change a frequency, change a rotational speed, change a transformer setting, actuate a switch, enable capacity back switching, adjust a parameter of a voltage regulator, and/or adjusting a variable resistance.

The spectral correlation function is determined by: defining a discrete-time signal model for a power grid signal; transforming the discrete-time signal model into a matrix based on a channelization length and a length of a hopping block; decreasing a spectral leakage between frequency channels by tapering data in the matrix; obtaining a frequency-domain representation of the power grid signal using the tapered data; processing the frequency-domain representation of the power grid signal to adjust time delays in frequency components; determining a correlation between same variables in successive time intervals; adjusting values of the frequency-domain representation based on the determined correlation; and performing time smoothing filtration of the adjusted values to obtain the spectral correlation function.

The present disclosure further concerns a system for monitoring, and detecting distortions of, power-grid signals. The system comprises: training circuitry; monitoring circuitry configured to monitor power-grid signals; and a data processing apparatus. The training circuitry configured to: obtain training power-grid signals known to be disturbance-free or have disturbances of predetermined types; determine respective spectral correlation functions (SCFs) of the training power-grid signals; and train, based on the training power-grid signals' SCFs, a model for classifying power-grid signals by their disturbances' predetermined type. The data processing apparatus is configured to: receive from the monitoring circuitry a monitored power-grid signal; determine an SCF for the monitored power-grid signal; access the trained model; classify, by applying the trained model to the monitored power-grid signal's SCF, the monitored power-grid signal as being disturbance-free or as having one of the predetermined disturbance types; and notify the monitoring circuitry of the monitored power-grid signal's disturbance type based on a result of the classification.

The model can include, but is not limited to, a convolutional neural network. In order to determine a power-grid signal's SCF, the training circuitry and the data processing apparatus each may be configured to perform operations described in connection with FIG. 1. In order to determine the power-grid signal's SCF, the training circuitry and the data processing apparatus each may be configured to perform operations (a)-(f) of FIG. 1. The predetermined type of disturbance can include, but is not limited to, arcing jumper, blown fuse, switching, low amplitude arcing, or transformer energization. The power-grid signals may comprise current signals.

The terms “processor” and “processing device” refer to a hardware component of an electronic device that is configured to execute programming instructions. Except where specifically stated otherwise, the singular terms “processor” and “processing device” are intended to include both single-processing device embodiments and embodiments in which multiple processing devices together or collectively perform a process.

The terms “memory,” “memory device,” “computer-readable medium,” “data store,” “data storage facility” and the like each refer to a non-transitory device on which computer-readable data, programming instructions or both are stored. Except where specifically stated otherwise, the terms “memory,” “memory device,” “computer-readable medium,” “data store,” “data storage facility” and the like are intended to include single device embodiments, embodiments in which multiple memory devices together or collectively store a set of data or instructions, as well as individual sectors within such devices. A computer program product is a memory device with programming instructions stored on it.

As used in this document, the singular form “a”, “an”, and “the” include plural references unless the context clearly dictates otherwise. Unless defined otherwise, all technical and scientific terms used herein have the same meanings as commonly understood by one of ordinary skill in the art. As used in this document, the term “comprising” means “including, but not limited to”.

The described features, advantages and characteristics disclosed herein may be combined in any suitable manner. One skilled in the relevant art will recognize, in light of the description herein, that the disclosed systems and/or methods can be practiced without one or more of the specific features. In other instances, additional features and advantages may be recognized in certain scenarios that may not be present in all instances.

Although the systems and methods have been illustrated and described with respect to one or more implementations, equivalent alterations and modifications will occur to others skilled in the art upon the reading and understanding of this specification and the annexed drawings. In addition, while a particular feature may have been disclosed with respect to only one of several implementations, such feature may be combined with one or more other features of the other implementations as may be desired and advantageous for any given or particular application. Thus, the breadth and scope of the disclosure herein should not be limited by any of the above descriptions. Rather, the scope of the invention should be defined in accordance with the following claims and their equivalents.

What is claimed is:

1. A method for operating a power grid-based system, comprising:
determining, by the processor, a spectral correlation function for a power grid signal being monitored;
applying, by the processor, a trained classification model to the spectral correlation function, the trained classification model comprising a machine learning model trained to classify power grid signals based on power grid signal distortions;
assigning, by the processor, a power grid distortion classification to the power grid signal based on an output of the trained classification model; and
controlling an operation of an electrical device of the power grid-based system based on the power grid distribution classification.

2. The method according to claim 1, wherein the electrical device comprises a power grid system, a component of the power grid system, or a monitoring circuit monitoring power signals of the power grid signal.

3. The method according to claim 1, wherein said controlling comprises: instructing a monitoring circuit to more or less frequently monitor a power grid signal from a particular component of the power grid-based system; and/or instructing a component of the power grid-based system to change an output voltage, change an output current, change a power level, change a frequency, change a rotational speed, change a transformer setting, actuate a switch, enable capacity back switching, adjust a parameter of a voltage regulator, and/or adjust a variable resistance.

4. The method according to claim 1, further comprising training one or more classification models to classify power grid signals based on power grid signal distortions.

5. The method according to claim 1, wherein the assigned power grid distortion classification comprises disturbance-free, arcing jumper, blown fuse, switching, low amplitude arcing, or transformer energization.

6. The method according to claim 1, wherein the spectral correlation function is determined by defining a discrete-time signal model for a power grid signal.

7. The method according to claim 6, wherein the spectral correlation function is determined by further transforming the discrete-time signal model into a matrix based on a channelization length and a length of a hopping block.

8. The method according to claim 7, wherein the spectral correlation function is determined by further decreasing a spectral leakage between frequency channels by tapering data in the matrix.

9. The method according to claim 8, wherein the spectral correlation function is determined by further: obtaining a frequency-domain representation of the power grid signal using the tapered data; and processing the frequency-domain representation of the power grid signal to adjust time delays in frequency components.

10. The method according to claim 9, wherein the spectral correlation function is determined by further: determining a correlation between same variables in successive time intervals; adjusting values of the frequency-domain representation based on the determined correlation; and performing time smoothing filtration of the adjusted values to obtain the spectral correlation function.

11. A system, comprising:
a processor; and
a non-transitory computer-readable storage medium comprising programming instructions that are configured to cause the processor to implement a method for operating a power grid-based system, wherein the programming instructions comprise instructions to:
determine a spectral correlation function for a power grid signal being monitored;
apply a trained classification model to the spectral correlation function, the trained classification model comprising a machine learning model trained to classify power grid signals based on power grid signal distortions;
assign a power grid distortion classification to the power grid signal based on an output of the trained classification model; and
control an operation of an electrical device of the power grid-based system based on the power grid distribution classification.

12. The system according to claim 11, wherein the electrical device comprises a power grid system, a component of the power grid system, or a monitoring circuit monitoring power signals of the power grid signal.

13. The system according to claim 11, wherein said operation of an electrical device is controlled by: instructing a monitoring circuit to more or less frequently monitor a power grid signal from a particular component of the power grid-based system; and/or instructing a component of the power grid-based system to change an output voltage, change an output current, change a power level, change a frequency, change a rotational speed, change a transformer setting, actuate a switch, enable capacity back switching, adjust a parameter of a voltage regulator, and/or adjusting a variable resistance.

14. The system according to claim 11, wherein the programming instructions further comprise instructions to train one or more classification models to classify power grid signals based on power grid signal distortions.

15. The system according to claim 11, wherein the assigned power grid distortion classification comprises disturbance-free, arcing jumper, blown fuse, switching, low amplitude arcing, or transformer energization.

16. The system according to claim 11, wherein the spectral correlation function is determined by defining a discrete-time signal model for a power grid signal.

17. The system according to claim 16, wherein the spectral correlation function is determined by further transforming the discrete-time signal model into a matrix based on a channelization length and a length of a hopping block.

18. The system according to claim 17, wherein the spectral correlation function is determined by further decreasing a spectral leakage between frequency channels by tapering data in the matrix.

19. The system according to claim 18, wherein the spectral correlation function is determined by further: obtaining a frequency-domain representation of the power grid signal using the tapered data; and processing the frequency-domain representation of the power grid signal to adjust time delays in frequency components.

20. The system according to claim 19, wherein the spectral correlation function is determined by further: determining a correlation between same variables in successive time intervals; adjusting values of the frequency-domain representation based on the determined correlation; and performing time smoothing filtration of the adjusted values to obtain the spectral correlation function.
